(19) United States
(12) Patent Application Publication
(10) Pub. No.: US 2025/0291371 A1
(43) Pub. Date: Sep. 18, 2025

(54) CONTROL METHOD, CONTROL DEVICE, AND STORAGE MEDIUM

(71) Applicant: Tokyo Electron Limited, Tokyo (JP)

(72) Inventors: Satoshi NAKAYAMA, Nirasaki City (JP); Shun FUKAMI, Nirasaki City (JP)

(21) Appl. No.: 19/077,236

(22) Filed: Mar. 12, 2025

(30) Foreign Application Priority Data
Mar. 15, 2024 (JP) 2024-041549

(51) Int. Cl. G05D 7/06; G05D 16/20

(52) U.S. Cl. CPC G05D 7/0635; G05D 16/2013

(57) ABSTRACT

A method of controlling a substrate processing apparatus, in which a gas is supplied from a tank to a chamber via a first valve, includes: calculating a predicted value of a tank pressure difference which is a difference between a tank pressure at a time point and a tank pressure after a lapse of a predetermined time from the time point; calculating a predicted value of a gas discharge flow rate from the tank to the chamber after the lapse of the predetermined time from the time point, based on the predicted value of the tank pressure difference; determining an open degree of the first valve such that an error between the predicted value of the gas discharge flow rate and a target value thereof is minimized; and adjusting an actual open degree of the first valve to match the determined open degree of the first valve.

### CROSS-REFERENCE TO RELATED APPLICATION

This application is based upon and claims the benefit of priority from Japanese Patent Application No. 2024-041549, filed on Mar. 15, 2024, the entire contents of which are incorporated herein by reference.

### TECHNICAL FIELD

The present disclosure relates to a control method, a control device, and a storage medium.

### BACKGROUND

Substrate processing such as etching or film formation on substrates, such as semiconductor wafers, glass substrates, or flat panel substrates, is performed in a chamber. For example, a tank that stores a predetermined gas required for processing is disposed on an upstream side of a chamber, and with a substrate disposed in the chamber, the gas flows from the tank into the chamber to perform the processing. Patent Document 1 discloses an example of a substrate processing apparatus that performs substrate processing.

### PRIOR ART DOCUMENT

### Patent Document

Patent Document 1: Japanese Patent Laid-open Publication No. 2022-053439

### SUMMARY

A control method according to one embodiment of the present disclosure is a control method of controlling a substrate processing apparatus including a tank that stores a predetermined gas, a first valve that discharges the gas from the tank, and a chamber into which the gas is supplied from the tank via the first valve and in which substrate processing is performed. The control method includes: calculating, based on tank pressure which is an internal pressure of the tank, a chamber pressure which is an internal pressure of the chamber, and an open degree of the first valve, a predicted value of a tank pressure difference which is a difference between a tank pressure at a time point and a tank pressure after a lapse of a predetermined time from the time point; calculating a predicted value of a gas discharge flow rate from the tank to the chamber after the lapse of the predetermined time from the time point, based on the calculated predicted value of the tank pressure difference; determining the open degree of the first valve such that an error between the calculated predicted value of the gas discharge flow rate and a target value of the gas discharge flow rate is minimized; and adjusting an actual open degree of the first valve to match the determined open degree of the first valve.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a block diagram illustrating a functional configuration example of a substrate processing apparatus.

FIG. 2 is a block diagram illustrating an internal functional configuration example of a control device.

FIG. 3 is a flowchart illustrating an example of a sequence in a process of collectively determining open degrees of a first valve at a plurality of time points, which is executed by a control device according to Embodiment 1.

FIG. 4 is a conceptual diagram illustrating an example of a function of a tank pressure difference estimation model according to Embodiment 1.

FIG. 5 is a conceptual diagram illustrating a configuration example of the tank pressure difference estimation model according to Embodiment 1.

FIG. 6 is a diagram illustrating an example of contents of a tank pressure difference table.

FIG. 7 is a conceptual diagram illustrating an example of a function of a chamber pressure difference estimation model according to Embodiment 1.

FIG. 8 is a conceptual diagram illustrating a configuration example of the chamber pressure difference estimation model according to Embodiment 1.

FIG. 9 is a diagram illustrating an example of contents of a chamber pressure difference table.

FIG. 10 is a conceptual diagram illustrating an example of contents of open degree data.

FIG. 11 is a flowchart illustrating an example of a sequence in a process of adjusting an open degree of the first valve actually by the control device.

FIG. 12 is a conceptual diagram illustrating an example of contents of open degree data after correcting an open degree of the first valve.

FIG. 13 is a flowchart illustrating an example of a sequence in a process of collectively determining opening degrees of a first valve at a plurality of time points, which is executed by the control device according to Embodiment 2.

FIG. 14 is a conceptual diagram illustrating an example of a function of a tank pressure difference estimation model according to Embodiment 2.

FIG. 15 is a conceptual diagram illustrating an example of a function of a chamber pressure difference estimation model according to Embodiment 2.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

### Embodiment 1

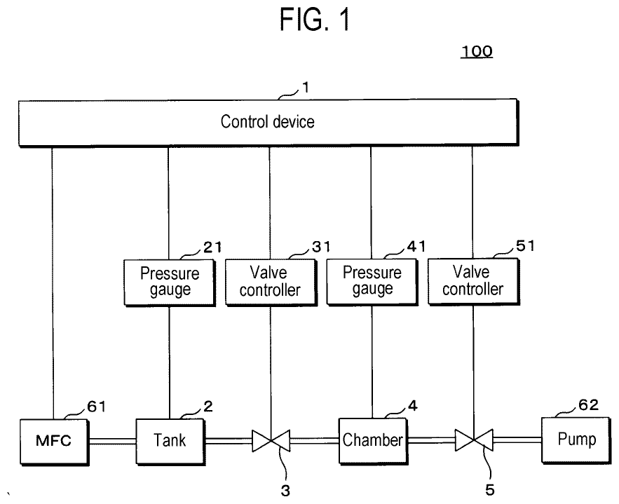

FIG. 1 is a block diagram illustrating a functional configuration example of a substrate processing apparatus 100. The substrate processing apparatus 100 includes a chamber 4 in which substrate processing such as etching or film formation is performed. A substrate is disposed in an interior of the chamber 4, and a predetermined gas such as an etching gas or a film formation gas is introduced into the interior of the chamber 4, and substrate processing such as etching or film formation is performed in the interior of the chamber 4. A tank 2 that stores the predetermined gas is connected to the chamber 4 via piping. A first valve 3 is provided in the piping connecting the chamber 4 and the tank 2. The first valve 3 is an opening/closing valve. A mass flow controller (MFC) 61 is connected to the tank 2 via piping.

The MFC 61 supplies the predetermined gas to the tank 2. For example, the MFC 61 supplies the gas to the tank 2 at a constant flow rate. While the first valve 3 is closed, the tank 2 does not discharge the gas and a supply of the gas from the MFC 61 continues, which increases a tank pressure, i.e., an internal pressure of the tank 2. When the first valve 3 is open, the gas is discharged from the tank 2 via the first valve 3. That is, the first valve 3 is opened to discharge the gas from the tank 2. While the first valve 3 is open, the gas is supplied from the tank 2 to the chamber 4 via the piping and the first valve 3.

The first valve 3 is a valve having an adjustable open degree. For example, the first valve 3 is a proportional control valve. The tank pressure changes according to a supply of the gas to the tank 2 and a discharge of the gas from the tank 2. By adjusting the open degree of the first valve 3, the tank pressure is adjusted, leading to adjustment of the gas discharge flow rate. The gas discharge flow rate refers to a flow rate of gas discharged from the tank 2 to the chamber 4, i.e., an amount of the gas discharged from the tank 2 per unit time. In general, the gas discharge flow rate increases as the open degree of the first valve 3 increases, and the gas discharge flow rate decreases as the open degree decreases.

A pump 62 is connected to the chamber 4 via piping. A second valve 5 is provided in the piping connecting the chamber 4 and the pump 62. The second valve 5 is an opening/closing valve having an adjustable open degree. For example, the second valve 5 is an automatic pressure control (APC) valve. The pump 62 operates to discharge the gas from the chamber 4. While the second valve 5 is open, the gas is discharged from the chamber 4 via the piping and the second valve 5 by the pump 62. The second valve 5 is opened to discharge the gas from the chamber 4. By adjusting the open degree of the second valve 5, an amount of the gas discharged from the chamber 4 is adjusted, leading to adjustment of a chamber pressure, i.e., an internal pressure of the chamber 4.

The tank 2 is provided with a pressure gauge 21, and the chamber 4 is provided with a pressure gauge 41. The pressure gauge 21 measures the tank pressure, and the pressure gauge 41 measures the chamber pressure. A valve controller 31 is connected to the first valve 3. The valve controller 31 performs opening and closing the first valve 3 as well as changing the open degree of the first valve 3. A valve controller 51 is connected to the second valve 5. The valve controller 51 performs opening and closing the second valve 5 as well as changing the open degree of the second valve 5.

A control device 1 is connected to the pressure gauge 21, the valve controller 31, the pressure gauge 41, the valve controller 51, and the MFC 61. The control device 1 acquires the tank pressure measured by the pressure gauge 21 and the chamber pressure measured by the pressure gauge 41. The control device 1 controls the valve controller 31, the valve controller 51, and the MFC 61. The control device 1 adjusts the open degree of the first valve 3 by controlling the valve controller 31. By adjusting the open degree of the first valve 3, the tank pressure is adjusted. The control device 1 adjusts the open degree of the second valve 5 by controlling the valve controller 51.

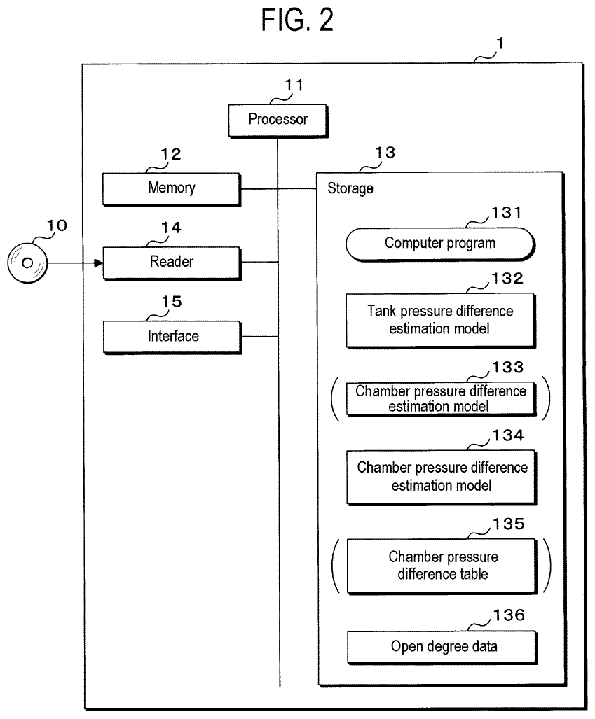

FIG. 2 is a block diagram illustrating an internal functional configuration example of the control device 1. The control device 1 executes a control method of controlling the substrate processing apparatus 100. The control device 1 is configured by using a computer such as a personal computer or a server device. The control device 1 includes a processor 11, a memory 12, a storage 13, a reader 14, and an interface 15. The processor 11 is configured by using, for example, a central processing unit (CPU), a graphics processing unit (GPU), or a multi-core CPU. The processor 11 may be configured by using a quantum computer. The memory 12 temporarily stores data generated according to calculations. The memory 12 is, for example, a random access memory (RAM). The storage 13 is non-volatile and is, for example, a hard disk or a non-volatile semiconductor memory. The reader 14 reads information from a recording medium 10 such as an optical disk or a portable memory.

The interface 15 is connected to the pressure gauge 21, the valve controller 31, the pressure gauge 41, the valve controller 51, and the MFC 61. The processor 11 acquires the tank pressure measured by the pressure gauge 21 and the chamber pressure measured by the pressure gauge 41 via the interface 15. The processor 11 controls the valve controller 31, the valve controller 51, and the MFC 61 by transmitting and receiving control signals via the interface 15.

The processor 11 causes the reader 14 to read a computer program (program product) 131 recorded on the recording medium 10, and stores the read computer program 131 in the storage 13. The processor 11 executes processing to implement functions of the control device 1 according to the computer program 131. The computer program 131 may be stored in advance in the storage 13, or may be downloaded to the control device 1 from outside. In this case, the control device 1 may not include the reader 14.

The computer program 131 may be expanded for execution on a single computer, or on multiple computers, which are disposed at a single site or distributed across multiple sites and are interconnected by a communication network. That is, the control device 1 may be configured by multiple computers, and the computer program 131 may be executed on multiple computers connected via a communication network. The control device 1 may be configured by using a cloud server.

Processing of each step, which will be described later, for executing a control method may be executed by multiple computers. The processing of each step may also be executed by different computers. Data used during the processing may be stored in multiple computers. The processing of each step may be executed by using a virtual machine. The processing of each step may be executed by multiple processors. The processing of each step may also be executed by different processors. For example, a part of the processing may be executed by a computer included in the substrate processing apparatus 100, while another part of the processing may be executed by a computer outside the substrate processing apparatus 100.

When a substrate is disposed in the interior of the chamber 4, a predetermined gas is supplied from the tank 2 to the chamber 4, and substrate processing is performed in chamber 4. In order to ensure appropriate substrate processing, it is necessary to appropriately adjust the internal pressure of the chamber 4. In order to adjust the internal pressure of the chamber 4, it is necessary to adjust the gas discharge flow rate from the tank 2 to the chamber 4. The control device 1 adjusts the open degree of the first valve 3 to adjust the gas discharge flow rate. Before a start of adjusting the open degree of the first valve 3 actually, the control device 1 performs a process of collectively determining open degrees of the first valve 3 at a plurality of future time points, so that an error between a predicted value and a target value of the gas discharge flow rate is minimized. After determining the open degrees of the first valve 3 at the plurality of future time points, the control device 1 performs a process of adjusting the open degree of the first valve 3 actually according to the determined opening degrees.

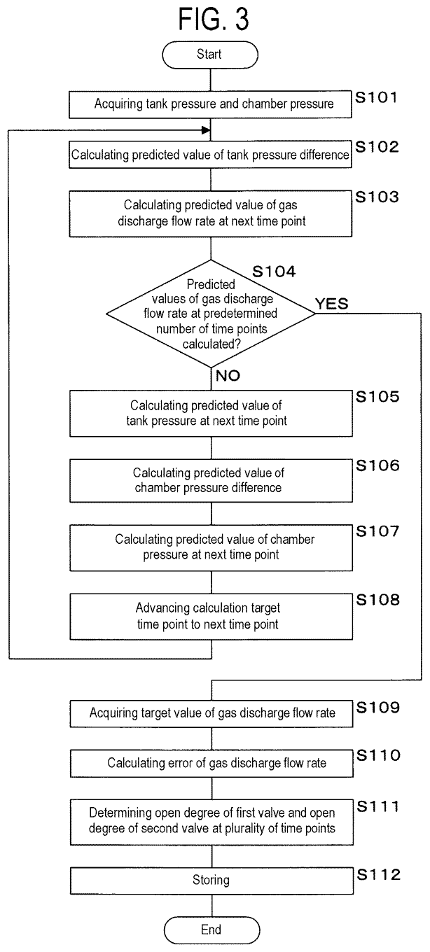

FIG. 3 is a flowchart illustrating an example of a sequence in a process of collectively determining open degrees of the first valve 3 at a plurality of time points, which is executed by the control device 1 according to Embodiment 1. Hereinafter, the term “step” is abbreviated as “S.” The control device 1 executes the following process by executing information processing by the processor 11 according to the computer program 131. The control device 1 acquires a latest tank pressure and a latest chamber pressure (S101). In S101, the processor 11 acquires a measured value of the tank pressure from the pressure gauge 21 via the interface 15. Further, the processor 11 acquires a measured value of the chamber pressure from the pressure gauge 41 via the interface 15. At this time, the processor 11 may acquire the tank pressures and chamber pressures at a plurality of past time points. The tank pressures and chamber pressures at the plurality of past time points have been stored in the storage 13, from which the processor 11 reads the stored past tank pressures and chamber pressures.

The control device 1 calculates a predicted value of a tank pressure difference, which is a difference between a tank pressure at a certain time point and a tank pressure at a next time point (S102). A time interval from the certain time point to the next time point is a predetermined duration. The control device 1 calculates the predicted value of the tank pressure difference by using a trained model. The control device 1 includes a tank pressure difference estimation model 132, which is a learned model. The tank pressure difference estimation model 132 is implemented by executing information processing by the processor 11 according to the computer program 131. The storage 13 stores data for implementing the tank pressure difference estimation model 132. The tank pressure difference estimation model 132 may be configured by hardware. The tank pressure difference estimation model 132 may be implemented by using a quantum computer. Alternatively, the tank pressure difference estimation model 132 may be provided outside the control device 1, and the control device 1 may be configured to execute processing by using the external tank pressure difference estimation model 132. For example, the tank pressure difference estimation model 132 may be configured by using a cloud.

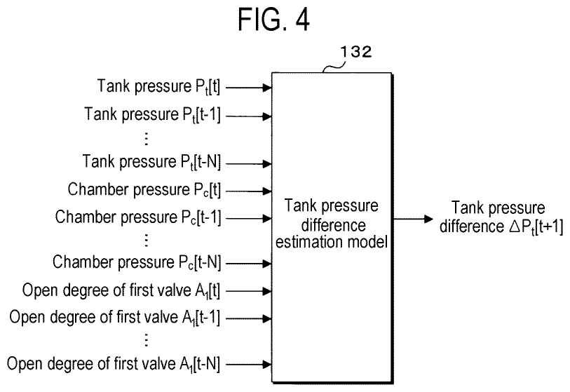

FIG. 4 is a conceptual diagram illustrating an example of a function of the tank pressure difference estimation model 132 according to Embodiment 1. A certain time point is denoted as t, a previous time point is denoted as t−1, a second previous time point is denoted as t−2, and an N-th previous time point is denoted as t−N. N is a positive integer and an arbitrary constant. A tank pressure at the certain time point is denoted as Pₜ[t], a tank pressure at the previous time point is denoted as Pₜ[t−1], and a tank pressure at the N-th previous time point N steps ago is denoted as Pₜ[t−N]. A chamber pressure at the certain time point is denoted as P_{c}[t], a chamber pressure at the previous time point is denoted as P_{c}[t−1], and a chamber pressure at the N-th previous time point is denoted as P_{c}[t−N]. An open degree of the first valve 3 at the certain time point is denoted as A₁[t], an open degree of the first valve 3 at the previous time point is denoted as A₁[t−1], and an open degree of the first valve 3 at the N-th previous time point is denoted as A₁[t−N]. The tank pressure difference estimation model 132 is learned in advance to output a tank pressure difference ΔPₜ[t+1] when N+1 tank pressures Pₜ[t], Pₜ[t−1], . . . , Pₜ[t−N], N+1 chamber pressures P_{c}[t], P_{c}[t−1], . . . , P_{c}[t−N], and N+1 open degrees A₁[t], A₁[t−1], . . . , A₁[t−N] of the first valve 3 are input. The tank pressure difference ΔPₜ[t+1] is a difference between the tank pressure Pₜ[t] at the certain time point and the tank pressure Pₜ[t+1] at the next time point.

The tank pressure difference is determined by the tank pressure at the certain time point and the tank pressure at the next time point, and the tank pressure at the next time point is affected by the open degree of the first valve 3 and the chamber pressure. For this reason, the tank pressure difference estimation model 132 is established to output the tank pressure difference based on the tank pressure, the open degree of the first valve 3, and the chamber pressure. In addition, the tank pressure is affected by the past tank pressure, and the past tank pressure is affected by the past open degree of the first valve 3 and the past chamber pressure. For this reason, the tank pressure difference estimation model 132 is established to output the tank pressure difference based on the current and past tank pressures, the current and past open degrees of the first valve 3, and the current and past chamber pressures. By using the tank pressure difference estimation model 132, it is possible to obtain the tank pressure difference easily.

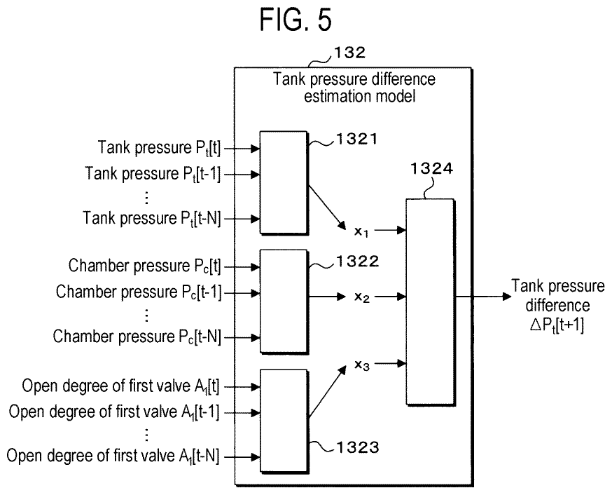

FIG. 5 is a conceptual diagram illustrating a configuration example of the tank pressure difference estimation model 132 according to Embodiment 1. The tank pressure difference estimation model 132 includes linear calculators 1321, 1322, and 1323, and a neural network 1324. The linear calculator 1321 receives the tank pressures Pₜ[t], Pₜ[t−1], . . . , Pₜ[t−N] as inputs, and outputs a value x₁. The linear calculator 1322 receives the chamber pressures P_{c}[t], P_{c}[t−1], . . . , P_{c}[t−N] as inputs, and outputs a value x₂. The linear calculator 1323 receives the open degrees A₁[t], A₁[t−1], . . . , A₁[t−N] of the first valve 3 as inputs, and outputs a value x₃. The linear calculators 1321, 1322, and 1323 calculate the values x₁, x₂, and x₃ by the following linear calculations with predetermined coefficients a₁₀, a₁₁, . . . , a_{1N}, b₁₀, b₁₁, . . . , b_{1N}, c₁₀, c₁₁, . . . , c_{1N}.

$${x}_{1} = {a}_{10} {P}_{t} [ t ] + {a}_{11} {P}_{t} [ t - 1 ] + … + {a}_{1 N} {P}_{t} [ t - N ]$$

$${x}_{2} = {b}_{10} {P}_{c} [ t ] + {b}_{11} {P}_{c} [ t - 1 ] + … + {b}_{1 N} {P}_{c} [ t - N ]$$

$${x}_{3} = {c}_{10} {A}_{1} [ t ] + {c}_{11} {A}_{1} [ t - 1 ] + … + {c}_{1 N} {A}_{1} [ t - N ]$$

The neural network 1324 receives the values x₁, x₂, and x₃ as inputs, and outputs the tank pressure difference ΔPₜ[t+1]. The tank pressure difference estimation model 132 may have various other configurations. The tank pressure difference estimation model 132 is learned in advance by using, as training data, data in which actually measured tank pressures, actually measured chamber pressures, actually measured open degrees of the first valve 3, and actually measured tank pressure differences are associated with one another.

In S102, the processor 11 inputs the tank pressures Pₜ[t], Pₜ[t−1], . . . , Pₜ[t−N], the chamber pressures P_{c}[t], P_{c}[t−1], . . . , P_{c}[t−N], and the open degrees A₁[t], A₁[t−1], . . . , A₁[t−N] of the first valve 3 to the tank pressure difference estimation model 132, and causes the tank pressure difference estimation model 132 to execute processing. The tank pressure difference estimation model 132 performs calculations based on inputs of the tank pressures, the chambers pressures, and the open degrees of the first valve 3 at a plurality of time points to output the tank pressure difference. The processor 11 acquires the tank pressure difference ΔPₜ[t+1] output by the tank pressure difference estimation model 132 as a predicted value of the tank pressure difference. As described above, the processor 11 calculates the predicted value of the tank pressure difference.

In S102, the processor 11 calculates a plurality of predicted values of the tank pressure difference based on a plurality of possible values, which can be taken as the open degree of the first valve 3. Specifically, the processor 11 inputs each of the plurality of possible values of the open degree of the first valve 3, as an open degree of the first valve 3 at a certain time point, to the tank pressure difference estimation model 132, and acquires predicted values of the tank pressure difference based on the respective possible values. As described above, the processor 11 calculates a predicted value of the tank pressure difference for each of the plurality of possible values of the open degree of the first valve 3.

The control device 1 may also be configured to calculate the predicted value of the tank pressure difference by using a regression model other than the learned model. The regression model is created by using actually measured tank pressures, actually measured chamber pressures, actually measured open degrees of the first valve 3, and actually measured tank pressure differences. The regression model may be implemented as a function.

The control device 1 may be configured to calculate the predicted value of the tank pressure difference by using a table instead of the learned model. In this configuration, the control device 1 uses a tank pressure difference table 133, in which a relationship among the tank pressure, the chamber pressure, the open degree of the first valve 3, and the tank pressure difference is recorded, instead of using the tank pressure difference estimation model 132. The storage 13 stores the tank pressure difference table 133.

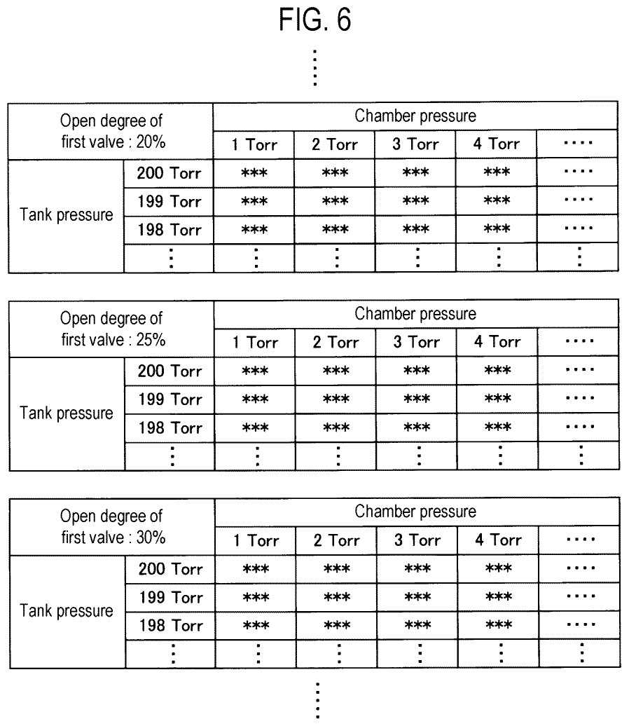

FIG. 6 is a diagram illustrating an example of contents of the tank pressure difference table 133. In the drawing, the pressure is illustrated in units of Torr, and the open degree of the first valve 3 is illustrated in units of %. Symbol “***” included in the drawing represents the tank pressure difference. A positive value for the tank pressure difference indicates that a tank pressure at a next time point is lower than a tank pressure at a certain time point. In the tank pressure difference table 133, a table, in which a value of the tank pressure difference in association with each combination of values of the tank pressure and values of the chamber pressure is recorded, is associated with each value of the open degree of the first valve 3. A plurality of values may be taken as the open degree of the first valve 3. Therefore, combinations of the tank pressure, the chamber pressure, and the tank pressure difference are associated with each value of the open degree of the first valve 3.

A value of the tank pressure difference obtained for a certain combination of values of the tank pressure, the chamber pressure, and the open degree of the first valve 3 is specified in advance through theoretical or experimental investigation. The previously specified value of the tank pressure difference is recorded in the tank pressure difference table 133. In S102, the processor 11 reads the tank pressure difference, which is associated with the tank pressure, the chamber pressure, and the open degree of the first valve 3 at a certain time point, from the tank pressure difference table 133. The processor 11 sets the read tank pressure difference as a predicted value of the tank pressure difference. As described above, the processor 11 calculates the predicted value of the tank pressure difference. In this configuration as well, the processor 11 calculates a predicted value of the tank pressure difference for each of a plurality of possible values, which can be taken as the open degree of the first valve 3. The processor 11 stores the calculated predicted value of the tank pressure difference in the storage 13.

The control device 1 calculates a predicted value of a gas discharge flow rate at a next time point (S103). In S103, the processor 11 calculates the predicted value of the gas discharge flow rate at the next time point, based on the predicted value of the tank pressure difference. A volume of a gas in the tank is denoted as V, an amount of substance of the gas is denoted as n, a gas constant is denoted as R, and a temperature is denoted as T. A predetermined time interval from ta certain time point to a next time point is denoted as Δt. An amount of substance of the gas at a certain time point is denoted as n[t]. A pressure of the gas at the certain time point is the tank pressure Pₜ[t].

By the gas state equation of Pₜ[t]V=nRT, the amount of substance of the gas at the certain time point is expressed as n[t]=Pₜ[t]V/RT, and the amount of substance of the gas at the next time point is expressed as n[t+1]=Pₜ[t+1]V/RT. Given that a change in the amount of substance of the gas up to the next time point is denoted as Δn and a change in the pressure of the gas is denoted as ΔP, Δn=n[t+1]−n[t]=(Pₜ[t+1]−Pₜ[t])/RT=ΔPV/RT. The gas discharge flow rate becomes Δn/Δt=Cx ΔPV/ΔtRT. Here, C is a conversion coefficient to convert a unit of a discharge flow rate from [mol/sec] to [standard cubic centimeter per minute (sccm)]. Specifically, C=1.34484×10⁶. The predicted value of the tank pressure difference ΔPₜ[t+1] may be used as the change in the pressure of the gasΔP. Therefore, the gas discharge flow rate is expressed by the following Equation (1).

$$Gas discharge flow rate = C \times Δ {P}_{t} [ t + 1 ] V / Δ tRT \qquad ( 1 )$$

The tank 2 is provided with a temperature sensor, and the control device 1 acquires an internal temperature of the tank 2 measured by the temperature sensor. The control device 1 stores in advance the conversion coefficient C, the internal volume V of the tank 2, the predetermined time interval Δt, and the gas constant R in the storage 13. The processor 11 performs the calculation of Equation (1) by using the predicted value of the tank pressure difference ΔPₜ[t+1] to determine a predicted value of the gas discharge flow rate. At this time, the processor 11 calculates a plurality of predicted values of the gas discharge flow rate based on a plurality of predicted values of the tank pressure difference. That is, the processor 11 calculates a predicted value of the gas discharge flow rate for each of a plurality of possible values, which can be taken as the open degree of the first valve 3. The processor 11 stores the calculated predicted value of the gas discharge flow rate in the storage 13.

Subsequently, the control device 1 determines whether predicted values of the gas discharge flow rate at a predetermined number of time points have been calculated (S104). The predetermined number is set in advance and is, for example, several hundreds. In S104, the processor 11 specifies the number of time points for which predicted values of the gas discharge flow rate have been calculated, and determines whether the specified number of time points has reached the predetermined number.

When predicted values of the gas discharge flow rate at the predetermined number of time points have not yet been calculated (S104: “NO”), the control device 1 calculates a predicted value of the tank pressure at a next time point (S105). In S105, the processor 11 calculates the tank pressure Pₜ[t+1] at the next time point by adding the predicted value of the tank pressure difference ΔPₜ[t+1] to the tank pressure Pₜ[t] at the certain time point. The processor 11 sets the calculated tank pressure as a predicted value of the tank pressure at the next time point. At this time, the processor 11 calculates a plurality of predicted values of the tank pressure at the next time point based on a plurality of predicted values of the tank pressure difference. The processor 11 stores the calculated predicted values of the tank pressure at the next time point in the storage 13.

The control device 1 calculates a predicted value of a chamber pressure difference, which is a difference between a chamber pressure at a certain time point and a chamber pressure at a next time point (S106). The control device 1 calculates a predicted value of the chamber pressure difference by using a learned model. The control device 1 includes a chamber pressure difference estimation model 134, which is a learned model.

The chamber pressure difference estimation model 134 is implemented by executing information processing by the processor 11 according to the computer program 131. The storage 13 stores data for implementing the chamber pressure difference estimation model 134. The chamber pressure difference estimation model 134 may be configured by hardware. The chamber pressure difference estimation model 134 may be implemented by using a quantum computer. Alternatively, the chamber pressure difference estimation model 134 may be provided outside the control device 1, and the control device 1 may be configured to execute processing by using the external chamber pressure difference estimation model 134. For example, the chamber pressure difference estimation model 134 may be configured by using a cloud.

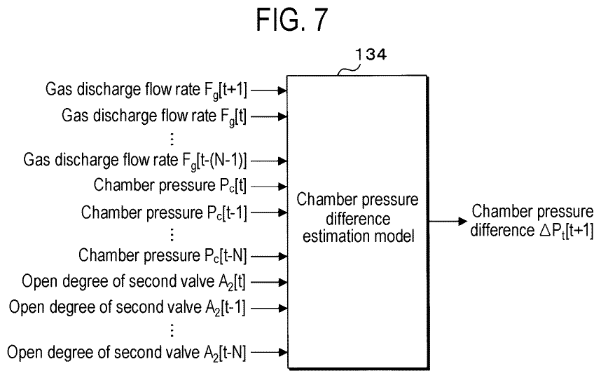

FIG. 7 is a conceptual diagram illustrating an example of a function of the chamber pressure difference estimation model 134 according to Embodiment 1. A gas discharge flow rate from a certain time point to a next time point is denoted as F_{g}[t+1]. An open degree of the second valve 5 at the certain time point is denoted as A₂[t], an open degree of the second valve 5 at a previous time point is denoted as A₂[t−1], and an open degree of the second valve 5 at an N-th previous time point is denoted as A₂[t−N]. The chamber pressure difference estimation model 134 is learned in advance to output a chamber pressure difference ΔP_{c}[t+1] when N+1 gas discharge flow rates F_{g}[t+1], F_{g}[t], . . . , F_{g}[t−(N−1)], N+1 chamber pressures P_{c}[t], P_{c}[t−1], . . . , P_{c}[t−N], and N+1 open degrees A₂[t], A₂[t−1], . . . , A₂[t−N] of the second valve 5 are input. The chamber pressure difference ΔP_{c}[t+1] is a difference between a chamber pressure P_{c}[t] at a certain time point and a chamber pressure P_{c}[t+1] at a next time point.

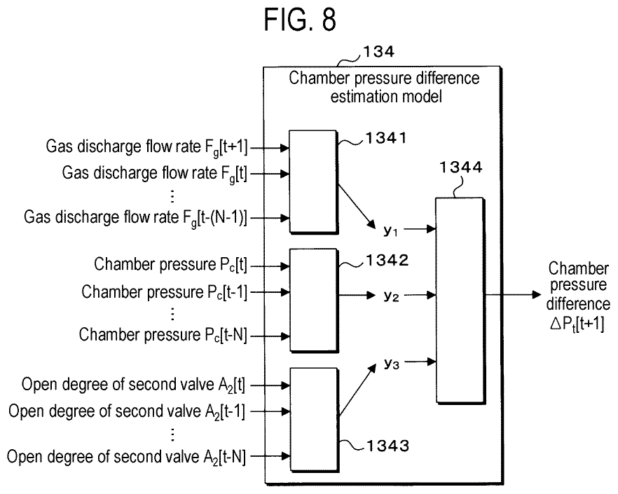

FIG. 8 is a conceptual diagram illustrating a configuration example of the chamber pressure difference estimation model 134 according to Embodiment 1. The chamber pressure difference estimation model 134 includes linear calculators 1341, 1342, and 1343, and a neural network 1344. The linear calculator 1341 receives the gas discharge flow rates F_{g}[t+1], F_{g}[t], . . . , F_{g}[t−(N−1)] as inputs, and outputs a value y₁. The linear calculator 1342 receives the chamber pressures P_{c}[t], P_{c}[t−1], . . . , P_{c}[t−N] as inputs, and outputs a value y₂. The linear calculator 1343 receives the open degrees A₂[t], A₂[t−1], . . . , A₂[t−N] of the second valve 5 as inputs, and outputs a value y₃. The linear calculators 1341, 1342, and 1343 calculate the values y₁, y₂, and y₃ by the following linear calculations with predetermined coefficients a₂₀, a₂₁, . . . , a_{2N}, b₂₀, b₂₁, . . . , b_{2N}, c₂₀, c₂₁, . . . , c_{2N}.

$${y}_{1} = {a}_{20} {F}_{g} [ t ] + {a}_{21} {F}_{g} [ t - 1 ] + … + {a}_{2 N} {F}_{g} [ t - N ]$$

$${y}_{2} = {b}_{20} {P}_{c} [ t ] + {b}_{21} {P}_{c} [ t - 1 ] + … + {b}_{2 N} {P}_{c} [ t - N ]$$

$${y}_{3} = {c}_{20} {A}_{2} [ t ] + {c}_{21} {A}_{2} [ t - 1 ] + … + {c}_{2 N} {A}_{2} [ t - N ]$$

The neural network 1344 receives the values y₁, y₂, and y₃ as inputs, and outputs the chamber pressure difference ΔP_{c}[t+1]. The chamber pressure difference estimation model 134 may have various other configurations. The chamber pressure difference estimation model 134 is learned in advance by using, as training data, data in which actually measured gas discharge flow rates, actually measured chamber pressures, actually measured open degrees of the second valve 5, and actually measured tank pressure differences are associated with one another.

In S106, the processor 11 inputs the gas discharge flow rates F_{g}[t+1], F_{g}[t], . . . , F_{g}[t−(N−1)], the chamber pressures P_{c}[t], P_{c}[t−1], . . . , P_{c}[t−N], and the open degrees A₂[t], A₂[t−1], . . . , A₂[t−N] of the second valve 5 to the chamber pressure difference estimation model 134, and causes the chamber pressure difference estimation model 134 to execute processing. The processor 11 uses the predicted value of the gas discharge flow rate calculated in S103 as the gas discharge flow rate F_{g}[t+1]. The chamber pressure difference estimation model 134 performs calculations based on the inputs of the gas discharge flow rates, the chamber pressures, and the open degrees of the second valve 5 at a plurality of time points to output the chamber pressure difference. The processor 11 acquires the chamber pressure difference ΔP_{c}[t+1] output by chamber pressure difference estimation model 134 as a predicted value of the chamber pressure difference. As described above, the processor 11 calculates the predicted value of the chamber pressure difference.

In S106, the processor 11 calculates a plurality of predicted values of the chamber pressure difference based on a plurality of predicted values of the gas discharge flow rate. In addition, the processor 11 calculates a plurality of predicted values of the chamber pressure difference based on a plurality of possible values, which can be taken as the open degree of the second valve 5. Specifically, the processor 11 inputs each of a plurality of possible values of the open degree of the second valve 5 at a certain time point to the chamber pressure difference estimation model 134, and acquires predicted values of the chamber pressure difference based on the respective possible values. As described above, the processor 11 calculates a predicted value of the chamber pressure difference for each of a plurality of possible values of the open degree of the second valve 5. The processor 11 stores the calculated predicted value of chamber pressure difference in the storage 13.

The control device 1 may also be configured to calculate the predicted value of the chamber pressure difference by using a regression model other than the learned model. The regression model is created by using data in which actually measured gas discharge flow rates, actually measured chamber pressures, actually measured open degrees of the second valve 5, and actually measured chamber pressure differences are associated with one another. The regression model may be implemented as a function.

The control device 1 may be configured to calculate the predicted value of the chamber pressure difference by using a table instead of the learned model. In this configuration, the control device 1 uses a chamber pressure difference table 135, in which a relationship among the gas discharge flow rate, the chamber pressure, the open degree of the second valve 5, and the chamber pressure difference is recorded, instead of using the chamber pressure difference estimation model 134. The storage 13 stores the chamber pressure difference table 135.

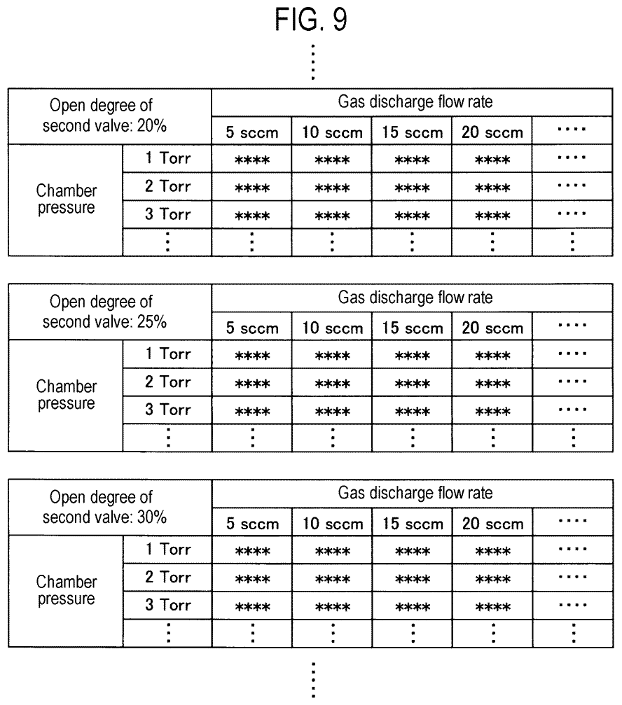

FIG. 9 is a diagram illustrating an example of contents of the chamber pressure difference table 135. In the drawing, the pressure is illustrated in units of Torr, the open degree of the second valve 5 is illustrated in units of %, and the gas discharge flow rate is illustrated in units of sccm. Symbol “****” included in the drawing represents the chamber pressure difference. A positive value for the chamber pressure difference indicates that a chamber pressure at a next time point is lower than a chamber pressure at a certain time point. In the chamber pressure difference table 135, a table, in which a value of the chamber pressure difference in association with each combination of values of the chamber pressure and values of the gas discharge flow rate are recorded, is associated with each value of the open degree of the second valve 5. A plurality of values may be taken as the open degree of the second valve 5. Therefore, combinations of the chamber pressure, the gas discharge flow rate, and the chamber pressure difference are associated with each value of the open degree of the second valve 5.

A value of the chamber pressure difference obtained for a certain combination of values of the chamber pressure, the gas discharge flow rate, and the open degree of the second valve 5 is specified in advance theoretical or experimental investigation. The previously specified value of the chamber pressure difference is recorded in the chamber pressure difference table 135. In S106, the processor 11 reads the chamber pressure difference, which is associated with the chamber pressure, the predicted value of the gas discharge flow rate obtained in S103, and the open degree of the second valve 5 at a certain time point, from the chamber pressure difference table 135. The processor 11 sets the read chamber pressure difference as a predicted value of the chamber pressure difference. As described above, the processor 11 calculates the predicted value of the chamber pressure difference.

In this configuration as well, the processor 11 calculates a plurality of predicted values of the chamber pressure difference based on a plurality of predicted values of the gas discharge flow rate. In addition, the processor 11 calculates a plurality of predicted values of the chamber pressure difference based on a plurality of possible values, which can be taken as the open degree of the second valve 5. The processor 11 stores the calculated predicted values of the chamber pressure difference in the storage 13.

The control device 1 calculates a predicted value of a chamber pressure at a next time point (S107). In S107, the processor 11 calculates the chamber pressure P_{c}[t+1] at the next time point by adding the predicted value of the chamber pressure difference ΔP_{c}[t+1] to the chamber pressure P_{c}[t] at the certain time point. The processor 11 sets the calculated chamber pressure as a predicted value of the chamber pressure at the next time point. At this time, the processor 11 calculates a plurality of predicted values of the chamber pressure at the next time point based on a plurality of predicted values of the chamber pressure difference. The processor 11 stores the calculated predicted values of the chamber pressure at the next time point in the storage 13.

Subsequently, the control device 1 advances a calculation target time point to the next time point (S108) and returns the processing to S102. The processor 11 changes a time point for which a predicted value of the gas discharge flow rate is to be calculated to the next time point, and repeats the processing from S102 to S108. That is, the “next time point” until now becomes the “certain time point,” and the processing from S102 to S108 is performed for this “certain time point.” In the next iteration of the processing from S102 to S108, the processor 11 uses the predicted value of the tank pressure calculated in S105 and the predicted value of the chamber pressure calculated in S107 as the tank pressure and the chamber pressure at the certain time point, respectively.

The processor 11 calculates predicted values of the gas discharge flow rate at a plurality of time points by repeating the processing from S102 to S108. For each time point, a plurality of predicted values of the tank pressure difference, as well as a plurality of predicted values of the gas discharge flow rate and the tank pressure at a next time point of each time point, are calculated based on a plurality of possible values of the open degree of the first valve 3. In addition, predicted values of the chamber pressure difference and the chamber pressure at the next time point of each time point are calculated based on a plurality of possible values of the open degree of the second valve 5. The predicted values of the tank pressure and the chamber pressure are used for calculations in the next time point of each time point. For this reason, the open degree of the second valve 5 also affects the predicted value of the gas discharge flow rate. For a single time point, a predicted value of the gas discharge flow rate is calculated for each of a plurality of possible combinations of the open degree of the first valve 3 and the open degree of the second valve 5, and similarly, a predicted value of the gas discharge flow rate is calculated for each time point. As a result, predicted values of the gas discharge flow rate at a plurality of time points are calculated for each of a plurality of possible combinations of the open degree of the first valve 3 and the open degree of the second valve 5 at a plurality of time points.

When the control device 1 has calculated predicted values of the gas discharge flow rate at the predetermined number of time points (S104: “YES”), the control device 1 acquires a target value of the gas discharge flow rate (S109). Target values of the gas discharge flow rate at a plurality of time points are stored in advance in the storage 13. In S109, the processor 11 acquires target values of the gas discharge flow rate at a plurality of time points by reading the target values of the gas discharge flow rate from the storage 13. The control device 1 may be configured to receive target values input by a user.

Subsequently, the control device 1 calculates an error between the predicted value of the gas discharge flow rate and the target value of the gas discharge flow rate (S110). In S110, the processor 11 calculates a squared value of a difference between the predicted value of the gas discharge flow rate and the target value of the gas discharge flow rate at each time point, and calculates, as the error, a sum of the calculated squared values over a plurality of time points. The processor 11 may calculate, as the error, a sum of an absolute value of a difference between the predicted value of the gas discharge flow rate and the target value of the gas discharge flow rate at each time point, over a plurality of time points. The processor 11 may also calculate, as the error, an absolute value of a sum of a difference between the predicted value of the gas discharge flow rate and target value of the gas discharge flow rate at each time point, over a plurality of time point. The processor 11 calculates the error for each of a plurality of possible combinations of the open degree of the first valve 3 and the open degree of the second valve 5 at a plurality of time points. That is, the processor 11 calculates the error by using the predicted values of the gas discharge flow rate at a plurality of time points, which have been calculated for each of the plurality of combinations.

Subsequently, the control device 1 determines the open degree of the first valve 3 and the open degree of the second valve 5 at a plurality of time points such that the error in the gas discharge flow rate is minimized as much as possible (S111). In S111, the processor 11 selects, from among a plurality of possible combinations of the open degree of the first valve 3 and the open degree of the second valve 5 at a plurality of time points, a combination that minimizes the calculated error. The processor 11 determines the open degree of the first valve 3 and the open degree of the second valve 5 at each time point according to the selected combination. As described above, the control device 1 collectively determines the open degrees of the first valve 3 at a plurality of future time points.

In addition, the control device 1 may also use an error in the chamber pressure to determine the open degree of the first valve 3 and the open degree of the second valve 5. In this case, the storage 13 stores target values of the chamber pressure at a plurality of time points, and the processor 11 calculates an error between the predicted value of the chamber pressure and the target value of the chamber pressure. The error is, for example, a sum of a squared value or an absolute value of a difference between the predicted value of the chamber pressure and the target value of the chamber pressure at each time point, or an absolute value of a sum of a difference between the predicted value of the chamber pressure and the target value of the chamber pressure at each time point, over a plurality of time points. The processor 11 selects, from among a plurality of possible combinations of the open degree of the first valve 3 and the open degree of the second valve 5 at a plurality of time points, a combination that minimizes a sum of the error in the gas discharge flow rate and the error in the chamber pressure. The processor 11 determines the open degree of the first valve 3 and the open degree of the second valve 5 at each time point according to the selected combination.

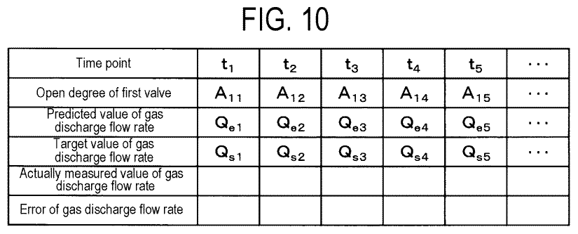

The control device 1 stores the determined open degrees of the first valve 3 at a plurality of time points (S112). The processor 11 generates open degree data 136 in which the determined open degrees of the first valve 3 at a plurality of time points are recorded, and stores the generated open degree data 136 in the storage 13. FIG. 10 is a conceptual diagram illustrating an example of contents of the opening degree data 136. A plurality of time points are represented as t₁, t₂, . . . , respectively. In the open degree data 136, the open degree of the first valve 3 is recorded in association with each time point. As illustrated in FIG. 10, the predicted value of the gas discharge flow rate and the target value of the gas discharge flow rate may also be recorded in the open degree data 136. In addition, the open degree of the second valve 5 may also be recorded in the open degree data 136.

After S112 ends, the control device 1 ends the process of collectively determining the open degrees of the first valve 3 at a plurality of time points. The open degrees of the first valve 3 at a plurality of future time points are determined by the processing from S101 to S112. After the processing from S101 to S112 ends, the control device 1 performs a process of adjusting the open degree of the first valve 3 actually.

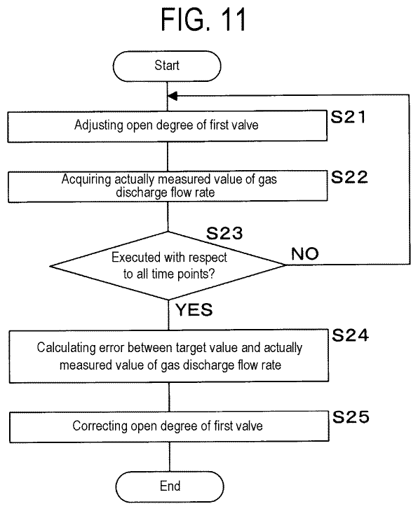

FIG. 11 is a flowchart illustrating an example of a sequence in a process of adjusting the open degree of the first valve 3 actually by the control device 1. The control device 1 adjusts an actual open degree of the first valve 3 according to the determined open degree of the first valve 3 (S21). In S21, the processor 11 reads a value of the open degree of the first valve 3 associated with a current time point from the opening degree data 136. The processor 11 sends a control signal for setting the open degree of the first valve 3 to the read value of the open degree, from the interface 15 to the valve controller. The valve controller 31 controls the first valve 3 in response to the control signal so that the open degree of the first valve 3 becomes the value of the open degree read from the open degree data 136. As described above, the actual open degree of the first valve 3 is adjusted to become the determined open degree of the first valve 3.

The control device 1 may adjust the open degree of the second valve 5 in parallel with the adjustment of the open degree of the first valve 3. For example, the open degree of the second valve 5 at each time point determined by the processing from S101 to S112 is recorded in the open degree data 136, the control device 1 adjusts an actual open degree of the second valve 5 to become the determined open degree of the second valve 5.

The control device 1 acquires an actually measured value of the gas discharge flow rate from the tank 2 to the chamber 4 (S22). In S22, the processor 11 acquires the actually measured value of the gas discharge flow rate by converting a differential pressure of the tank 2 into a flow rate. Specifically, the processor 11 acquires the tank pressure at the current time point by using the pressure gauge 21, and calculates the differential pressure of the tank 2 by subtracting the tank pressure at the current time point from a predicted value of the tank pressure at a next time point. The processor 11 calculates the actually measured value of the gas discharge flow rate by multiplying the differential pressure of the tank 2 by a conversion coefficient that converts a pressure to a flow rate. The conversion coefficient is stored in advance in the storage 13. The processor 11 stores the actually measured value of the gas discharge flow rate in the storage 13. For example, the processor 11 records the actually measured value of the gas discharge flow rate in the open degree data 136 in association with the current time point.

In S22, the processor 11 may also acquire the actually measured value of the gas discharge flow rate by using a conductance value of the tank 2. Specifically, the processor 11 acquires the tank pressure and the chamber pressure at the current time point by using the pressure gauges 21 and 41, calculates the differential pressure of the tank 2, and calculates a differential pressure of chamber 4 by subtracting the chamber pressure at the current time point from a predicted value of the chamber pressure at a next time point. The processor 11 calculates the actually measured value of the gas discharge flow rate by subtracting the differential pressure of the chamber 4 from the differential pressure of the tank 2 and multiplying the subtraction result by the conductance value. The conductance value is stored in advance in the storage 13. The processor 11 stores the actually measured value of the gas discharge flow rate in the storage 13.

The control device 1 determines whether the adjustment of the open degree of the first valve 3 has been executed with respect to all time points for which the open degree of the first valve 3 has been determined (S23). When there is a time point at which the open degree of the first valve 3 has not been adjusted (S23: “NO”), the control device 1 returns the processing to S21 and adjusts the open degree of the first valve 3 at a next time point. When the adjustment of the open degree of the first valve 3 has been executed with respect to all the time points for which the open degree of the first valve 3 has been determined (S23: “YES”), the control device 1 calculates an error between the target value of the gas discharge flow rate and the actually measured value of the gas discharge flow rate (S24). In S24, the processor 11 calculates the error between the target value of the gas discharge flow rate and the actually measured value of the gas discharge flow rate by subtracting the actually measured value of the gas discharge flow rate from the target value of the gas discharge flow rate at each time point. The processor 11 records the error for each time point in the open degree data 136 in association with each time point.

Subsequently, the control device 1 corrects the open degree of the first valve 3 based on the calculated error (S25). In S25, the processor 11 corrects the open degree of the first valve 3 by subtracting a value, which is obtained by multiplying the error between the target value of the gas discharge flow rate and the actually measured value of the gas discharge flow rate at each time point by a predetermined coefficient, from the open degree of the first valve 3 at each time point. Various other methods of correcting the open degree of the first valve 3 may also be used. For example, the processor 11 may calculate a correction amount of the open degree based on the error between the target value of the gas discharge flow rate and the actual measured value of the gas discharge flow rate by using a feedback control method such as proportional-integral-differential (PID) control, and may correct the open degree of the first valve 3 by subtracting the correction amount of the open degree from the open degree of the first valve 3. The processor 11 records a corrected value of the open degree of the first valve 3 at each time point in the open degree data 136.

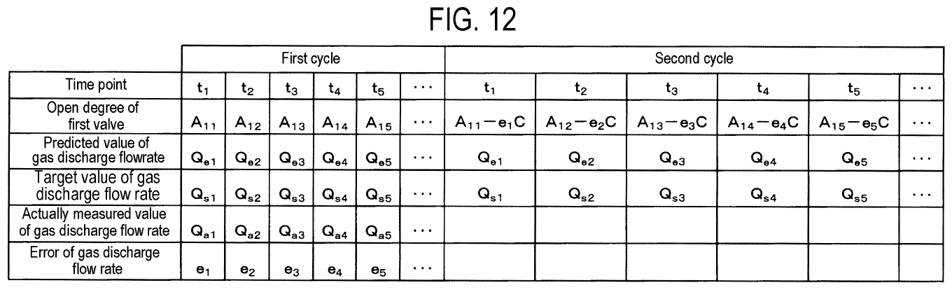

FIG. 12 is a conceptual diagram illustrating an example of contents of the open degree data 136 after correcting the open degree of the first valve 3. A plurality of time points at which the open degree of the first valve 3 is adjusted by the processing from S21 to S25 are collectively referred to as a first cycle. A next plurality of time points at which the open degree of the first valve 3 needs to be adjusted are collectively referred to as a second cycle. Each time point included in the first cycle is associated with the error between the target value of the gas discharge flow rate and the actually measured value of the gas discharge flow rate. Each time point included in the second cycle is associated with the corrected value of the open degree of the first valve 3.

After S25 ends, the control device 1 ends the process of adjusting the actual opening degree of the first valve 3. By executing the processing from S21 to S25, the control device 1 sequentially applies the determined open degrees of the first valve 3 at a plurality of time points to the first valve 3. As described above, the control device 1 adjusts the open degrees of the first valve 3 at a plurality of time points. Thereafter, the control device 1 adjusts the open degree of the first valve 3 at each time point included in the second cycle by executing the processing from S21 to S25 again by using the open degree data 136 after the correction of the open degree of the first valve 3. Similarly, the control device 1 adjusts the open degree of the first valve 3 at each time point included in third and subsequent cycles by repeating the processing from S21 to S25.

As described above in detail, the control device 1 determines the open degree of the first valve 3 such that the error between the predicted value of the gas discharge flow rate, which is in accordance with the tank pressure, the chamber pressure, and the open degree of the first valve 3, and the target value of the gas discharge flow rate is minimized as much as possible. The tank pressure difference is calculated based on the tank pressure, the chamber pressure, and the open degree of the first valve 3, and the predicted value of the gas discharge flow rate is calculated based on the tank pressure difference. The control device 1 adjusts the actual open degree of the first valve 3 to become the determined open degree of the first valve 3. Since the open degree of the first valve 3 is determined to minimize the error between the predicted value of the gas discharge flow rate, which is obtained based on the open degree of the first valve 3, and the target value of the gas discharge flow rate, it is possible to adjust the open degree of the first valve 3 with high precision. By adjusting the open degree of the first valve 3 with high precision, it is possible to adjust a gas discharge amount from the tank 2 to the chamber 4 with high precision.

By adjusting the gas discharge amount from the tank 2 to the chamber 4 with high precision, the chamber pressure is adjusted with high precision. Since the substrate processing apparatus 100 can adjust the chamber pressure with high precision, it is possible to stabilize the chamber pressure during substrate processing in the chamber 4, and to execute the substrate processing stably. In addition, by setting the target value of the gas discharge flow rate appropriately, the control device 1 can arbitrarily adjust a temporal change in the gas discharge flow rate.

In the present embodiment, the control device 1 collectively determines the open degrees of the first valve 3 at a plurality of time points, prior to adjusting the actual open degrees of the first valve 3. The control device 1 adjusts the actual open degrees of the first valve 3 based on the determined open degrees at a plurality of time points. In order to determine the open degrees of the first valve 3 with high precision, a certain amount of processing time is required. By collectively determining the open degrees of the first valve 3 at a plurality of time points and then adjusting the actual open degrees of the first valve 3, the control device 1 can adjust the open degrees of the first valve 3 at appropriate timings with high precision without being affected by the processing time required for determining the open degrees.

By collectively determining the open degrees of the first valve 3 at a plurality of time points, it becomes possible to use, as the error between the predicted value of the gas discharge flow rate and the target value of the gas discharge flow rate, the absolute value of the sum of the differences between the predicted value and the target value over a plurality of time points, or the sum of the squared values of the differences over a plurality of time points. By using the error described above, the open degrees of the first valve 3 are determined to minimize an average of the differences between the predicted value of the gas discharge flow rate and the target value of the gas discharge flow rate over a plurality of time points. Accordingly, the control device 1 can adjust the opening degrees of the first valve 3 with high precision, and adjust the gas discharge amount from the tank 2 to the chamber 4 with high precision, over a certain period of time.

In the present embodiment, the control device 1 repeats adjusting the actual open degrees of the first valve 3 a plurality of cycles by using the determined open degrees of the first valve 3 at a plurality of time points. Thus, the control device 1 can adjust the open degrees of the first valve 3 and adjust the gas discharge amount from the tank 2 to the chamber 4, over a long period of time. In addition, the control device 1 corrects the open degrees of the first valve 3 at a plurality of time points based on the error between the target value of the gas discharge flow rate and the actual measured value of the gas discharge flow rate. Even when an error is generated between the target value of the gas discharge flow rate and the actual measured value of the gas discharge flow rate, the open degrees of the first valve 3 are corrected according to the error, and thus it is possible to adjust the gas discharge flow rate with higher precision. Therefore, the control device 1 can adjust the gas discharge amount with high precision over a long period of time.

### Embodiment 2

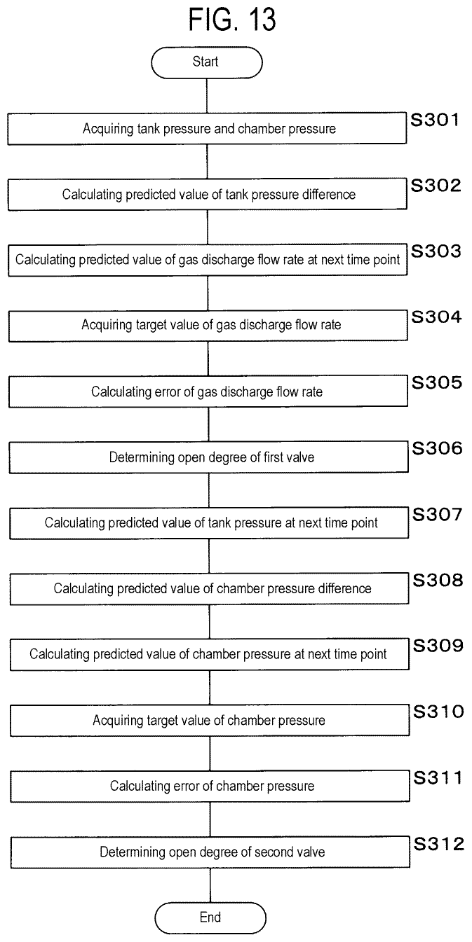

A configuration of the substrate processing apparatus 100 according to Embodiment 2 is similar to that of Embodiment 1. In Embodiment 2 as well, the control device 1 performs the process of collectively determining the open degrees of the first valve 3 at a plurality of future time points, prior to starting adjustment of the actual open degree of the first valve 3. FIG. 13 is a flowchart illustrating an example of a sequence in a process of collectively determining the open degrees of the first valve 3 at a plurality of time points, which is executed by the control device 1 according to Embodiment 2. The control device 1 acquires the tank pressure and the chamber pressure (S301).

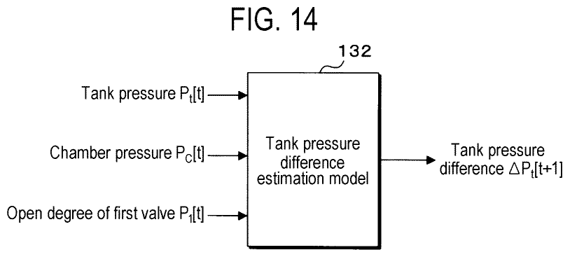

The control device 1 calculates a predicted value of the tank pressure difference (S302). The control device 1 calculates the predicted value of the tank pressure difference by using the tank pressure difference estimation model 132 (S302). FIG. 14 is a conceptual diagram illustrating an example of a function of the tank pressure difference estimation model 132 according to Embodiment 2. The tank pressure difference estimation model 132 is learned in advance to output a tank pressure difference ΔPₜ[t+1] when a tank pressure Pₜ[t] at a certain time point, a chamber pressure P_{c}[t] at the certain time point, and an open degree A₁[t] of the first valve 3 at the certain time point are input. The tank pressure difference estimation model 132 is learned in advance by using, as training data, data in which actually measured tank pressures, actually measured chamber pressures, actually measured open degrees of the first valve 3, and actually measured tank pressure differences are associated with one another.

In S302, the processor 11 inputs the tank pressure Pₜ[t], the chamber pressure P_{c}[t], and the open degree A₁[t] of the first valve 3 to the tank pressure difference estimation model 132, and causes the tank pressure difference estimation model 132 to execute processing. The tank pressure difference estimation model 132 performs calculations based on the inputs of the tank pressure, the chamber pressure, and the open degree of the first valve 3, and outputs the tank pressure difference. The processor 11 acquires the tank pressure difference ΔPₜ[t+1] output by the tank pressure difference estimation model 132 as a predicted value of the tank pressure difference. In S302, the processor 11 calculates a predicted value of the tank pressure difference for each of a plurality of possible values, which can be taken as the open degrees of the first valve 3.

The control device 1 may be configured to calculate the predicted value of the tank pressure difference by using the tank pressure difference table 133 instead of the tank pressure difference estimation model 132. The contents of the tank pressure difference table 133 are similar to those in Embodiment 1. In this configuration, the processor 11 reads the tank pressure difference, which is associated with the tank pressure, the chamber pressure, and the open degree of the first valve 3 at a certain time point, from the tank pressure difference table 133. The processor 11 sets the read tank pressure difference as a predicted value of the tank pressure difference. In this configuration as well, the processor 11 calculates a predicted value of the tank pressure difference for each of a plurality of possible values of the open degree of the first valve 3. The processor 11 stores the calculated predicted value of the tank pressure difference in the storage 13.

The control device 1 calculates a predicted value of the gas discharge flow rate at a next time point (S303). In S303, the processor 11 calculates the predicted value of the gas discharge flow rate at the next time point in the same manner as in Embodiment 1. At this time, the processor 11 calculates a predicted value of the gas discharge flow rate for each of a plurality of possible values of the open degree of the first valve 3. The processor 11 stores the calculated predicted value of the gas discharge flow rate in the storage 13.

The control device 1 acquires a target value of the gas discharge flow rate (S304). In S304, the processor 11 acquires the target value of the gas discharge flow rate by reading the target value of the gas discharge flow rate from the storage 13. The control device 1 may be configured to receive the target value input by a user. Subsequently, the control device 1 calculates an error between the predicted value of the gas discharge flow rate and the target value of the gas discharge flow rate (S305). In S305, the processor 11 calculates, as the error, an absolute value or a squared value of a difference between the predicted value of the gas discharge flow rate and the target value of the gas discharge flow rate. At this time, the processor 11 calculates the error for each of a plurality of possible combinations of the open degrees of the first valve 3.

Subsequently, the control device 1 determines the open degree of the first valve 3 such that the error in the gas discharge flow rate is minimized as much as possible (S306). In S306, the processor 11 selects, from among a plurality of possible values of the open degree of the first valve 3, a value that minimizes the calculated error, to determine the selected value as the open degree of the first valve 3. The processor 11 stores the determined open degree of the first valve 3 in the storage 13. Specifically, the processor 11 records the determined open degree of the first valve 3 in the open degree data 136 in association with the certain time point.

The control device 1 calculates a predicted value of the tank pressure at a next time point (S307). In S307, the processor 11 calculates the tank pressure Pₜ[t+1] at the next time point by adding the predicted value of the tank pressure difference ΔPₜ[t+1], which is obtained according to the determined open degree of the first valve 3, to the tank pressure Pₜ[t] at the certain time point. The processor 11 sets the calculated tank pressure as a predicted value of the tank pressure at the next time point. The processor 11 stores the calculated predicted value of the tank pressure in the storage 13.

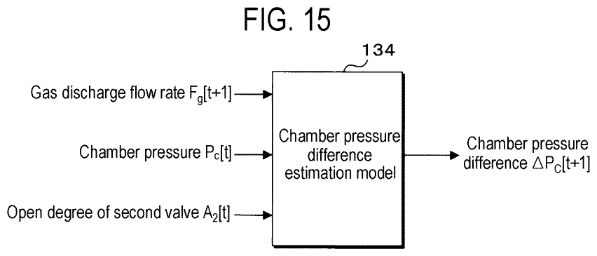

Subsequently, the control device 1 calculates a predicted value of the chamber pressure difference (S308). The control device 1 calculates the predicted value of the chamber pressure difference by using the chamber pressure difference estimation model 134 (S302). FIG. 15 is a conceptual diagram illustrating an example of a function of the chamber pressure difference estimation model 134 according to Embodiment 2. The chamber pressure difference estimation model 134 is learned in advance to output a chamber pressure difference ΔPc[t+1] when a gas discharge flow rate Fg[t+1], a chamber pressure Pc[t], and an open degree A2[t] of the second valve 5 are input. The chamber pressure difference estimation model 134 is learned in advance by using, as training data, data in which actually measured discharge flow rates, actually measured chamber pressures, actually measured open degrees of the second valve 5, and actually measured tank pressure differences are associated with one another.

In S308, the processor 11 inputs the gas discharge flow rate Fg[t+1], the chamber pressure Pc[t], and the open degree A2[t] of the second valve 5 to the chamber pressure difference estimation model 134, and causes the chamber pressure difference estimation model 134 to execute processing. The processor 11 uses the predicted value of the gas discharge flow rate calculated in S303 as the gas discharge flow rate F_{g}[t+1]. The chamber pressure difference estimation model 134 performs calculations based on the inputs of the gas discharge flow rate, the chamber pressure, and the open degree of the second valve 5, and outputs the chamber pressure difference. The processor 11 acquires the chamber pressure difference ΔP_{c}[t+1] output by the chamber pressure difference estimation model 134 as the predicted value of the chamber pressure difference. In S308, the processor 11 calculates a predicted value of the chamber pressure difference for each of a plurality of possible values of the open degree of the second valve 5.

The control device 1 may be configured to calculate the predicted value of the chamber pressure difference by using the chamber pressure difference table 135 instead of the tank pressure difference estimation model 134. The contents of the chamber pressure difference table 135 are similar to those in Embodiment 1. In this configuration, the processor 11 reads the chamber pressure difference, which is associated with the chamber pressure, the predicted value of the gas discharge flow rate obtained in S303, and the open degree of the second valve 5 at a certain time point, from the chamber pressure difference table 135. In this configuration as well, the processor 11 calculates a predicted value of the chamber pressure difference for each of a plurality of possible values of the open degree of the second valve 5. The processor 11 stores the calculated predicted value of the chamber pressure difference in the storage 13.

The control device 1 calculates a predicted value of the chamber pressure at a next time point (S309). In S309, the processor 11 calculates the predicted value of the chamber pressure at the next time point in the same manner as in Embodiment 1. At this time, the processor 11 calculates a predicted value of the chamber pressure for each of a plurality of possible values of the open degree of the second valve 5. The processor 11 stores the calculated predicted value of the chamber pressure in the storage 13.

The control device 1 acquires a target value of the chamber pressure (S310). In S310, the processor 11 acquires the target value of the chamber pressure by reading the target value of the chamber pressure from the storage 13. The control device 1 may be configured to receive the target value input by a user. Subsequently, the control device 1 calculates an error between the predicted value of the chamber pressure and the target value of the chamber pressure (S311). In S311, the processor 11 calculates, as the error, an absolute value or a squared value of a difference between the predicted value of the chamber pressure and the target value of the chamber pressure. At this time, the processor 11 calculates the error for each of a plurality of possible combinations of the open degrees of the second valve 5.

Subsequently, the control device 1 determines the open degree of the second valve 5 such that the error in the chamber pressure is minimized as much as possible (S312). In S312, the processor 11 selects, from among a plurality of possible values of the open degree of the second valve 5, a value that minimizes the calculated error. The processor 11 stores the determined open degree of the second valve 5 in the storage 13. For example, the processor 11 records the determined open degree of the second valve 5 in the open degree data 136 in association with the certain time point.

After S312 ends, the control device 1 ends the processing. The control device 1 repeats the processing from S301 to S312 at a next time point. The predicted value of the tank pressure calculated in S307 and the predicted value of the chamber pressure calculated in S309 are acquired as the tank pressure and the chamber pressure in S301 at the next time point. By repeating the processing from S301 to S312 multiple times, the control device 1 collectively determines the open degrees of the first valve 3 at a plurality of future time points. After the repetition of the processing from S301 to S312 ends, the control device 1 executes the processing from S21 to S25 to adjust the open degree of the first valve 3 actually, as in Embodiment 1.

The control device 1 may also be configured to execute the process of determining the open degree of the first valve 3 at each time point and adjusting the open degree of the first valve 3 in real time. In this configuration, the control device 1 executes the processing from S301 to S306, and after S306, adjusts the open degree of the first valve 3 actually to match the determined open degree of the first valve 3. Thereafter, the control device 1 executes the processing from S307 to S312, and after S312, adjusts the open degree of the second valve 5 actually to match the determined open degree of the second valve 5. The control device 1 repeats the above processing. In this configuration as well, the gas discharge flow rate from the tank 2 can be adjusted by adjusting the open degree of the second valve 5.

In the present embodiment as well, since the open degree of the first valve 3 is determined to minimize the error between the predicted value of the gas discharge flow rate, which is obtained based on the open degree of the first valve 3, and the target value of the gas discharge flow rate, the control device 1 can adjust the open degree of the first valve 3 with high precision. Therefore, the control device 1 can adjust the gas discharge amount from the tank 2 to the chamber 4 with high precision. The substrate processing apparatus 100 can adjust the chamber pressure with high precision, and can execute substrate processing stably.

The present disclosure is not limited to the contents of the above-described embodiments, and various modifications can be made within the scope of the claims. That is, embodiments obtained by combining technical means appropriately modified within the scope of the claims also fall within the technical scope of the present disclosure.

According to the present disclosure, it is possible to provide a control method, a control device, and a storage medium for adjusting a gas discharge flow rate from a tank with high precision.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A control method of controlling a substrate processing apparatus comprising a tank that stores a predetermined gas, a first valve that discharges the gas from the tank, and a chamber into which the gas is supplied from the tank via the first valve and in which substrate processing ais performed, the control method comprising:
calculating, based on a tank pressure which is an internal pressure of the tank, a chamber pressure which is an internal pressure of the chamber, and an open degree of the first valve, a predicted value of a tank pressure difference which is a difference between a tank pressure at a time point and a tank pressure after a lapse of a predetermined time from the time point;
calculating a predicted value of a gas discharge flow rate from the tank to the chamber after the lapse of the predetermined time from the time point, based on the calculated predicted value of the tank pressure difference;
determining the open degree of the first valve such that an error between the calculated predicted value of the gas discharge flow rate and a target value of the gas discharge flow rate is minimized; and
adjusting an actual open degree of the first valve to match the determined open degree of the first valve.

2. The control method of claim 1, wherein the predicted value of the gas discharge flow rate is calculated for a plurality of time points, and
wherein the error is either an absolute value of a sum of a difference between the predicted value of the gas discharge flow rate and the target value of the gas discharge flow rate at each of the plurality of time points over the plurality of the time points, or a sum of a squared value of the difference between the predicted value of the gas discharge flow rate and the target value of the gas discharge flow rate at each of the plurality of time points over the plurality of the time points.

3. The control method of claim 2, wherein the substrate processing apparatus further comprises a second valve that discharges the gas from the chamber, and
wherein the control method further comprises:
calculating a plurality of predicted values of the tank pressure difference based on the tank pressure, the chamber pressure, and a plurality of possible values of the open degree of the first valve;
calculating a plurality of predicted values of the tank pressure and a plurality of gas discharge flow rates at a next time point, based on the plurality of predicted values of the tank pressure difference;
calculating, with respect to each of the plurality of predicted values of the gas discharge flow rate, a plurality of predicted values of the chamber pressure at the next time point, based on the predicted value of the gas discharge flow rate, the chamber pressure, and a plurality of possible values of an open degree of the second valve;
repeating, based on the predicted value of the tank pressure, the predicted value of the chamber pressure, the plurality of possible values of the open degree of the first valve, and the plurality of possible values of the open degree of the second valve at a certain time point, calculation of a plurality of predicted values of the tank pressure difference, and calculation of a plurality of predicted values of the tank pressure, a plurality of gas discharge flow rates, and a plurality of chamber pressures at a next time point of the certain time point; and
determining the open degree of the first valve by selecting, from among a plurality of possible combinations of open degrees of the first valve at a plurality of time points, a combination that minimizes the error.

4. The control method of claim 3, further comprising:
calculating a predicted value of a chamber pressure difference which is a difference between a chamber pressure at a time point and a chamber pressure after a lapse of a predetermined time from the time point, based on the predicted value of the gas discharge flow rate, the chamber pressure, and the open degree of the second valve; and
calculating a predicted value of the chamber pressure after the lapse of the predetermined time from the time point, based on the calculated predicted value of the chamber pressure difference.

5. The control method of claim 4, wherein the calculating the predicted value of the tank pressure difference includes:
inputting the tank pressure, the chamber pressure, and the open degree of the first valve into a learned model, which outputs the predicted value of the tank pressure difference when the tank pressure, the chamber pressure, and the open degree of the first valve are input; and
acquiring the predicted value of the tank pressure difference output by the learned model.

6. The control method of claim 2, further comprising:
prior to the adjusting the actual open degree of the first valve, collectively determining open degrees of the first valve at a plurality of time points; and
sequentially applying the determined open degrees of the first valve at the plurality of time points to the first valve, to adjust actual open degrees of the first valve.

7. The control method of claim 6, wherein the sequentially applying the determined open degrees of the first valve at the plurality of time points to the first valve is repeated a plurality of cycles.

8. The control method of claim 7, further comprising:
when the open degrees of the first valve at the plurality of time points are sequentially applied to the first valve, acquiring actually measured values of the gas discharge flow rate at the plurality of time points;
calculating errors between the actually measured values of the gas discharge flow rate and target values of the gas discharge flow rate at the plurality of time points;
correcting the open degrees of the first valve at the plurality of time points by using the calculated errors; and
applying the corrected open degrees to the first valve in a next cycle.

9. The control method of claim 1, wherein the calculating the predicted value of the tank pressure difference includes:
inputting the tank pressure, the chamber pressure, and the open degree of the first valve into a learned model, which outputs the predicted value of the tank pressure difference when the tank pressure, the chamber pressure, and the open degree of the first valve are input; and
acquiring the predicted value of the tank pressure difference output by the learned model.

10. The control method of claim 1, wherein the calculating the predicted value of the tank pressure difference includes reading the tank pressure difference according to the tank pressure, the chamber pressure, and the open degree of the first valve, from a table in which a relationship among the tank pressure, the chamber pressure, the open degree of the first valve, and the tank pressure difference is recorded.

11. A control device for controlling a tank that stores a predetermined gas, a first valve that discharges the gas from the tank, and a chamber into which the gas is supplied from the tank via the first valve and in which substrate processing is performed, the control device comprising:
a processor,
wherein the processor is configured to execute:
calculating, based on a tank pressure which is an internal pressure of the tank, a chamber pressure which is an internal pressure of the chamber, and an open degree of the first valve, a predicted value of a tank pressure difference which is a difference between a tank pressure at a time point and a tank pressure after a lapse of a predetermined time from the time point;
calculating a predicted value of a gas discharge flow rate from the tank to the chamber after the lapse of the predetermined time from the time point, based on the calculated predicted value of the tank pressure difference;
determine the open degree of the first valve such that an error between the calculated predicted value of the gas discharge flow rate and a target value of the gas discharge flow rate is minimized; and
adjust an actual open degree of the first valve to match the determined open degree of the first valve.

12. A non-transitory computer-readable storage medium that stores a computer program, which causes a computer to execute a process of calculating a numerical values used to control a tank that stores a predetermined gas, a first valve that discharges the gas from the tank, and a chamber into which the gas is supplied from the tank via the first valve and in which substrate processing is performed, the process comprising:
calculating, based on a tank pressure which is an internal pressure of the tank, a chamber pressure which is an internal pressure of the chamber, and an open degree of the first valve, a predicted value of a tank pressure difference which is a difference between a tank pressure at a time point and a tank pressure after a lapse of a predetermined time from the time point;
calculating a predicted value of a gas discharge flow rate from the tank to the chamber after the lapse of the predetermined time from the time point, based on the calculated predicted value of the tank pressure difference; and
determining the open degree of the first valve such that an error between the calculated predicted value of the gas discharge flow rate and a target value of the gas discharge flow rate is minimized.
